(19) United States
(12) Patent Application Publication
(10) Pub. No.: US 2014/0220365 A1
(43) Pub. Date: Aug. 7, 2014

(54) LAMINATED ELECTRODE

(71) Applicants: Hideya YAMADERA, Nagoya-shi (JP); Masaaki TSUCHIMORI, Owariasahi-shi (JP); Takehiro KATO, Toyota-shi (JP); Takahiro ITO, Toyota-shi (JP)

(72) Inventors: Hideya YAMADERA, Nagoya-shi (JP); Masaaki TSUCHIMORI, Owariasahi-shi (JP); Takehiro KATO, Toyota-shi (JP); Takahiro ITO, Toyota-shi (JP)

(73) Assignee: TOYOTA JIDOSHA KABUSHIKI KAISHA, Toyota-shi (JP)

(21) Appl. No.: 14/168,544

(22) Filed: Jan. 30, 2014

(30) Foreign Application Priority Data
Feb. 4, 2013 (JP) 2013-019587

(51) Int. Cl. H01L 29/45

(52) U.S. Cl. CPC H01L 29/456; H01L 29/452
USPC 428/450

(57) ABSTRACT

A laminated electrode disposed on a substrate includes a first layer disposed at a top surface and a second layer directly joined to the first layer. A material of the first layer is gold. A material of the second layer is nickel silicide.

### CROSS-REFERENCE TO RELATED APPLICATION

This application claims priority to Japanese Patent Application No. 2013-019587 filed on Feb. 4, 2013, the contents of which are hereby incorporated by reference into the present application.

### TECHNICAL FIELD

The technique disclosed in the specification relates to a laminated electrode disposed on a substrate.

### DESCRIPTION OF RELATED ART

A laminated electrode disposed on a substrate is joined to various types of components via solder. For example, the laminated electrode on the substrate is joined to a lead frame, a wire, etc., via solder. Due to this, a nickel (Ni) layer having a satisfactory bondability and barrier property to solder is often used as a material of the laminated electrode. Further, in order to protect the nickel layer from oxidation, generally a gold (Au) layer is coated on a surface of the nickel layer. An example of a laminated electrode having such a nickel layer and gold layer laminated is disclosed in Japanese Patent Application Publication No. 2004-107734.

As an example of a lead-free solder, use of Sn-based solder is considered. However, according to studies conducted by the inventors, it has been found that, when a laminated electrode is placed under a high temperature after bonding using the Sn-based solder, Sn in the Sn-based solder is diffused to an interface of the laminated electrode and a substrate, whereby adhesion of the laminated electrode and the substrate is deteriorated.

The technique disclosed herein aims to provide a laminated electrode that can maintain adhesion with a substrate by preventing the aforementioned phenomenon from occurring.

### BRIEF SUMMARY OF THE INVENTION

The technique disclosed herein is implemented in a laminated electrode disposed on a substrate. The laminated electrode disclosed herein comprises a first layer disposed at a top surface; and a second layer directly joined to the first layer. A material of the first layer is gold. A material of the second layer is nickel silicide.

With the second layer formed of nickel silicide being provided, Sn in Sn-based solder is prevented from diffusing to an interface of the laminated electrode and the substrate. Due to this, even if the laminated electrode is placed under a high temperature after bonding the Sn-based solder, adhesion of the laminated electrode and the substrate is maintained.

### BRIEF DESCRIPTION OF DRAWINGS

FIG. 1 schematically shows a cross sectional view of a primary portion of a semiconductor device disclosed in the description;

FIG. 2 schematically shows a cross sectional view of a chip used in an adhesion strength evaluation test; and

FIG. 3 schematically shows a perspective view of a sample used in the adhesion strength evaluation test.

### DETAILED DESCRIPTION OF INVENTION

Representative, non-limiting examples of the present invention will now be described in further detail with reference to the attached drawings. This detailed description is merely intended to teach a person of skill in the art further details for practicing preferred aspects of the present teachings and is not intended to limit the scope of the invention. Furthermore, each of the additional features and teachings disclosed below may be utilized separately or in conjunction with other features and teachings to provide improved laminated electrodes, as well as methods for using and manufacturing the same.

Moreover, combinations of features and steps disclosed in the following detail description may not be necessary to practice the invention in the broadest sense, and are instead taught merely to particularly describe representative examples of the invention. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

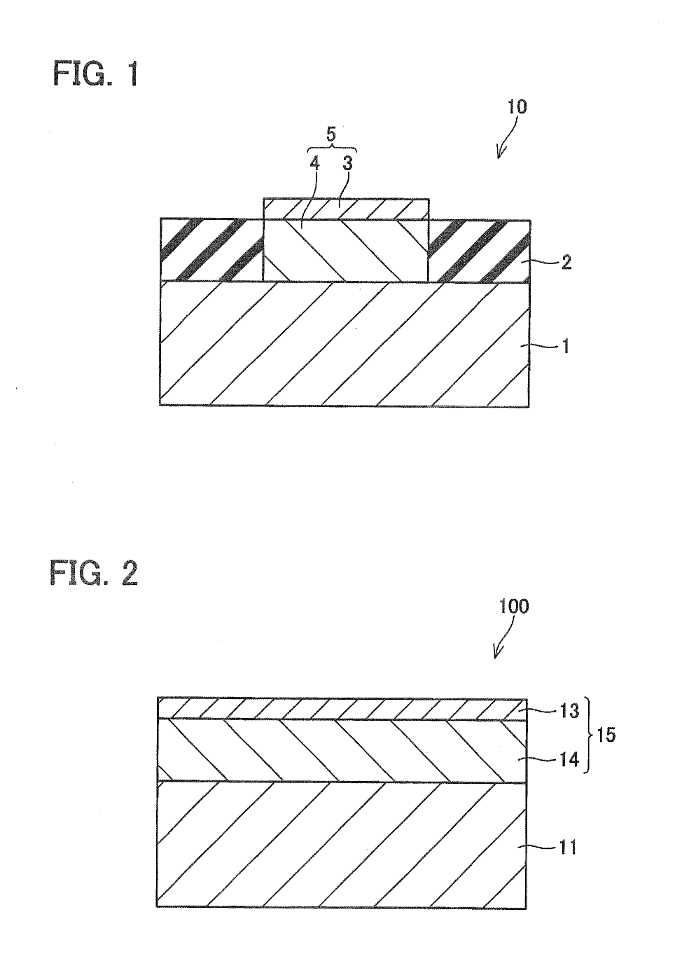

As shown in FIG. 1, a semiconductor device 10 includes a substrate 1, an insulating film 2, and a laminated electrode 5. The substrate 1 is an element substrate on which an element that exhibits a specific function is formed. The substrate 1 in one example is a semiconductor substrate on which a circuit element is formed, and more specifically may be a silicon substrate. Alternatively, silicon carbide (SiC) substrate, a gallium nitride (GaN) substrate, etc. may be used as the substrate 1. A power semiconductor element such as an IGBT, MOSFET, diode, etc. may be formed on the substrate 1. The insulating film 2 covers a part of a surface of the substrate 1. In one example, silicon oxide is used as a material of the insulating film 2.

The laminated electrode 5 is disposed on a part of the surface of the substrate 1, and includes, in the following order from its top surface, a surface layer 3, and a nickel silicide layer 4. The surface layer 3 is disposed at the top surface of the laminated electrode 5, covers a surface of the nickel silicide layer 4, and protects the nickel silicide layer 4 from oxidation. A material of the surface layer 3 is gold (Au). The surface layer 3 is formed on the surface of the nickel silicide layer 4 for example by using a sputtering technique.

The nickel silicide layer 4 is disposed between the surface layer 3 and the substrate 1, and is disposed so as to be directly joined to both the surface layer 3 and the substrate 1. The nickel silicide layer 4 directly makes contact with a surface of the substrate 1, and electrically makes an ohmic contact with an impurity region that configured the power semiconductor element. A material of the nickel silicide layer 4 may be an intermetallic compound of nickel and silicon. In one example, the material of the nickel silicide layer 4 may include at least one compound selected from the group consisting of Ni₃Si, Ni₂Si, Ni₃Si₂ and NiSi. The nickel silicide layer 4 is formed on the surface of the substrate 1 for example by using the sputtering technique. Notably, other metallic layers such as an aluminum layer or a titanium layer may be disposed between the nickel silicide layer 4 and the substrate 1.

In the semiconductor device 10 having the above configuration, Sn-based solder is applied to the surface of the laminated electrode 5, and a lead frame, a wire, and the like are joined thereto by reflow. Thereafter, even if the laminated electrode 5 is placed under a high temperature, Sn included in the Sn-based solder is prevented from diffusing to the substrate 1 by passing through the nickel silicide layer 4. Thus, adhesion of the laminated electrode 5 and the substrate 1 is maintained.

(Adhesion Strength Evaluation Test)

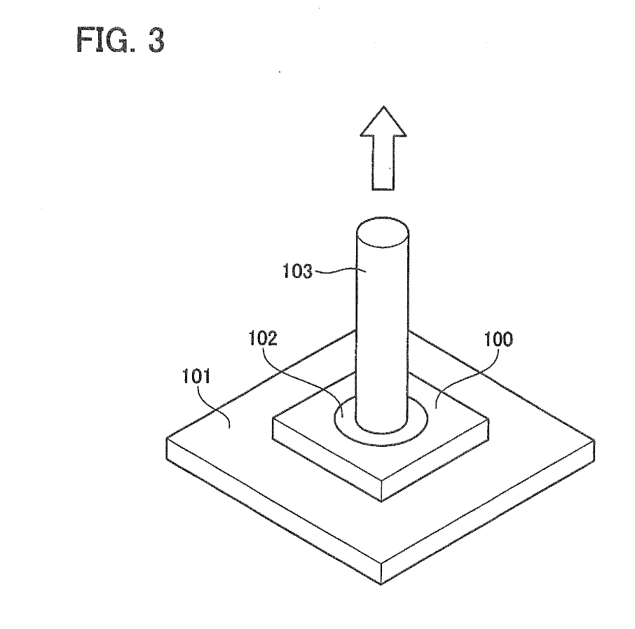

A test sample chip 100 as shown in FIG. 2 was prepared, and an adhesion strength evaluation test of a laminated electrode 15 was conducted. The test sample chip 100 as shown in FIG. 2 was prepared was prepared by the following procedures. Firstly, a substrate 11 that is a p-type silicon (100) substrate (diameter 100 mm×thickness 0.5 mm, 1 Ω·cm) was prepared. Next, a nickel-silicon alloy layer 14 and a surface layer 13 were orderly formed on the substrate 11 by using a sputtering technique. A material of the nickel-silicon alloy layer 14 is nickel alloy containing silicon, and a thickness thereof is about 1 μm. A material of the surface layer 13 is gold, and a thickness thereof is about 0.1 μm. Then, after having formed the substrate 11 into square chips that each is 10 mm on each side, a thermal treatment is performed to silicide the nickel-silicon alloy layer 14. Hereafter, the nickel-silicon alloy layer 14 that had been silicided will specifically be called a nickel silicide layer 14. Conditions of the thermal treatment were 400° C. under nitrogen atmosphere containing 10% of hydrogen for 30 minutes. Next, as shown in FIG. 3, Sn-based solder 102 was reflowed on a surface of the test sample chip 100, and a Cu pin 103 was soldered. A material of the Sn-based solder 102 was Sn—Cu. Conditions of the reflow were 277° C. for 3 minutes. Finally, the prepared test sample chip 100 was firmly joined onto a pedestal 101, and a sample for the adhesion strength evaluation test was prepared thereby.

The adhesion strength evaluation test was conducted by a tensile test that pulls the Cu pin 103 relative to the test sample chip 100 in a vertical direction after having placed the prepared sample in a high temperature oven at 200° C. for 168 hours (high temperature oven stand-still processing) (see FIG. 3). Evaluation criteria were set as that those of which substrate 11 breaks when a stress that is at about the same degree as a fracture strength of the substrate 11 is applied are “accepted”, and those of which an interface of the substrate 11 and the laminated electrode 15 breaks when a stress that is smaller than the fracture strength of the substrate 11 is applied are “failed”. Further, a state of element distribution at the interface of the substrate 11 and the laminated electrode 15 was measured by using an AES (Auger Electron Spectroscopy) method. Table 1 shows a result of the adhesion strength evaluation test.

TABLE 1

| | | | Adhesion | | |
|---|---|---|---|---|---|
| | | | (Before | Adhesion | |
| | | | Thermal | (After Thermal | |
| | Composition of | Crystal Phase of | Treatment) | Treatment) | |
| Sample | Electrode Material | Ni—Si | (N/mm²) | (N/mm²) | Adhesiveness |
| Product of | Au/Ni—25 at. % Si | Ni₃Si | 10.8 | 10.2 | Satisfactory |
| Example 1 | | | | | |
| Product of | Au/Ni—28 at. % Si | Ni₃Si + Ni₂Si | 12.2 | 11.2 | Satisfactory |
| Example 2 | | | | | |
| Product of | Au/Ni—37 at. % Si | Ni₂Si + NiSi | 10.7 | 11.8 | Satisfactory |
| Example 3 | | | | | |
| Product of | Au/Ni—45 at. % Si | Ni₂Si + NiSi | 10.5 | 9.8 | Satisfactory |
| Example 4 | | | | | |
| Product of | Au/Ni—50 at. % Si | NiSi | 11.2 | 11.4 | Satisfactory |
| Example 5 | | | | | |
| Product of | Au/Ni | Ni | 8.7 | 3.8 | Failed |
| Comparative | | | | | |
| Example 1 | | | | | |
| Product of | Au/Ni—10 at. % Si | Ni + Amorphous | 8.2 | 4.7 | Failed |
| Comparative | | | | | |
| Example 2 | | | | | |
| Product of | Au/Ni—28 at. % Si | Amorphous | 7.9 | 5.2 | Failed |
| Comparative | | | | | |
| Example 3 | | | | | |

Here, the products of examples 1 to 5 respectively have silicon content in the nickel silicide layer 14 of 25 at. %, 28 at. %, 37 at. %, 45 at. %, and 50 at. %, and all of the crystal phase of the nickel silicide layer 14 is an inter metallic compound of nickel and silicon. The product of comparative example 1 is an example that does not contain silicon in a layer corresponding to the nickel silicide layer 14 of the products of examples 1 to 5. The products of comparative examples 2 and 3 are examples of which silicon content in the layer corresponding to the nickel silicide layer 14 of the products of examples 1 to 5 is 10 at. %, and 28 at. %, respectively, and the crystal phase of the aforementioned layer is amorphous. Notably, the adhesion shown in Table 1 was calculated from the fracture strength and a fracture area.

As shown in Table 1, all of the products of examples 1 to 5 exhibited breakage at the substrate 11 in their samples after the high temperature oven stand-still processing, and the evaluation of being “satisfactory” was given. Further, all of the products of examples 1 to 5 maintained their adhesion before and after the high temperature oven stand-still processing. On the other hand, all of the products of comparative examples 1 to 3 exhibited exfoliation of the laminated electrode 15 from the substrate 11 in their samples after the high temperature oven stand-still processing, and the evaluation of being “failed” was given.

Table 2 indicates a state of element distribution at a joint portion of the substrate 11 and the laminated electrode 15 in the product of example 2 and the product of comparative example 1.

TABLE 2

| | | | Element | | |
|---|---|---|---|---|---|
| | | Crystal | Composition of | | |
| | | Phase | Electrode/Substrate | | |
| | Composition of | of | Interface (at. %) | | |
| Sample | Electrode Material | Ni—Si | Sn | Ni | Si |
| Product of | Au/Ni—28 at. % Si | Ni₂Si | 0 | 33 | 67 |
| Example 1 | | | | | |
| Product of | Au/Ni | Ni | 16 | 42 | 42 |
| Comparative | | | | | |
| Example 1 | | | | | |

As shown in Table 2, in the product of comparative example 1, Sn was observed at the joint portion of the substrate 11 and the laminated electrode 15. This Sn is assumed to have diffused from the Sn-based solder 102. Since Sn has weak adhesion with the substrate 11, in the product of comparative example 1, it is assumed that the adhesion of the substrate 11 and the laminated electrode 15 has decreased due to Sn diffusing to the joint portion of the substrate 11 and the laminated electrode 15. On the other hand, in the product of example 2, Sn was not observed at the joint portion of the substrate 11 and the laminated electrode 15. From this result, in the product of example 2, it is assumed that Sn in the Sn-based solder 102 is prevented from diffusion to the joint portion of the substrate 11 and the laminated electrode 15, and the adhesion had been maintained due to the layer 14 being configured of the nickel silicide.

Further, from the result of the above, the followings are assumed.
(1) As shown in the products of comparative examples 1 and 2, when the silicon content in the nickel silicide layer 14 is small, the adhesion significantly decreases after the high temperature oven stand-still processing than before the above processing. Due to this, if the silicon content of the nickel silicide layer 14 is small, it is assumed that the effect of preventing the diffusion of Sn from the Sn-based solder 102 is deteriorated. Thus, as has been confirmed with the products of examples 1 to 5, the silicon content of the nickel silicide layer 14 is preferably 25 to 50 at. %.
(2) As shown in the product of comparative example 3, even if the silicon content of the layer corresponding to the nickel silicide layer 14 is in the range of 25 to 50 at. %, if the crystal phase of the aforementioned layer is amorphous, it is difficult to maintain the adhesion before and after the high temperature oven stand-still processing. Due to this, it is preferable that the laminated electrode 15 is provided with the nickel silicide layer 14 that is the intermetallic compound of nickel and silicon.

What is claimed is:

1. A laminated electrode disposed on a substrate, the laminated electrode comprising:
a first layer disposed at a top surface; and
a second layer directly joined to the first layer, wherein
a material of the first layer is gold, and
a material of the second layer is nickel silicide.

2. The laminated electrode according to claim 1, wherein
the nickel silicide is an intermetallic compound of nickel and silicon.

3. The laminated electrode according to claim 1, wherein
an atomic ratio of the silicon in the second layer is 25 to 50%.

4. The laminated electrode according to claim 1, wherein
the material of the second layer includes at least one compound selected from the group consisting of Ni₃Si, Ni₂Si, Ni₃Si₂ and NiSi.
